(19) United States
(12) Patent Application Publication
(10) Pub. No.: US 2013/0264618 A1
(43) Pub. Date: Oct. 10, 2013

(54) METHOD FOR MANUFACTURING BACKSIDE-ILLUMINATED IMAGE SENSOR

(71) Applicant: DONGBU HITEK CO., LTD., Gyeonggi-do (KR)

(72) Inventors: Chung Kyung JUNG, Gyeonggi-do (KR); Sungwook Joo, Gyeonggi-do (KR)

(73) Assignee: Dongbu HiTek Co., Ltd., Gyeonggi-do (KR)

(21) Appl. No.: 13/760,503

(22) Filed: Feb. 6, 2013

(30) Foreign Application Priority Data
Apr. 4, 2012 (KR) 10-2012-0035061

(51) Int. Cl. H01L 33/00

(52) U.S. Cl. CPC H01L 33/0041
USPC 257/290; 438/59

(57) ABSTRACT

A method for manufacturing a backside-illuminated image sensor includes (1) forming an isolation film on the front side of a semiconductor substrate with a buried insulating layer formed therein to define an active region; (2) forming a light-receiving element in the active region of the semiconductor substrate; and (3) forming an inter-layer dielectric layer on the front side of the semiconductor substrate on which the light-receiving element is formed. The method may include forming a super contact hole to pass through the inter-layer dielectric layer and the buried insulating layer in a pad region defined on the front side of the semiconductor substrate reaching the semiconductor substrate. The method may include forming a barrier layer of a metal oxide film containing transition metal at the bottom and sidewall of the super contact hole. The method may include filling a conductive material in the super contact hole, in which the barrier layer is formed, to form a super contact.

The present application claims priority to Korean Patent Application No. 10-2012-0035061 (filed on Apr. 4, 2012), which is hereby incorporated by reference in its entirety.

### BACKGROUND

Light generated from subjects in the natural world has a unique wavelength value or range of values. An image sensor captures an image of each subject using properties of a semiconductor apparatus that responsive to external energy. The pixels of an image sensor detect light generated from each subject and convert the detected light to electrical values.

Semiconductor image sensors may be classified into a charge coupled devices (CCD) based on a silicon semiconductor and CMOS image sensors using a technique for manufacturing a sub-micron CMOS (Complementary Metal Oxide Semiconductor).

A CCD has a structure in which individual MOS capacitors are relatively close to each other and charge carriers are stored in the capacitors and transferred during operation. A CCD may have limitations due to relatively complex driving methods that often need to be used, power consumption is relatively high, and the number of mask process steps is relatively large, creating challenges to implementation of signal processing circuits in a CCD chip. CMOS image sensors has been developed and studied, which have advantages over CCDs.

A CMOS image sensor is implemented by forming a photodiode (PD) and a MOS transistor in a unit pixel to detect a signal in a switching manner. A CMOS image sensor may have advantages of relatively low production costs, relatively low power consumption, and relative ease of integration into a peripheral circuit chip compared to a CCD. Since CMOS image sensors are produced by the CMOS manufacturing technique, CMOS image sensors may be easily integrated into peripheral systems, such as amplification and signal processing systems, which may minimize production costs. CMOS image sensors may have relatively high processing speeds and relatively low power consumption that may be as advantageous as 1% of a CCD.

In CMOS image sensors, the photodiode may be formed in a semiconductor substrate through ion implantation. As the size of a photodiode is miniaturized, an increase in the number of pixels on a chip may be accomplished, without increasing the size of the chip. In some applications, area of a light receiving area may be minimized. The stack height may not be reduced by the reduced light receiving area. Accordingly, a backside-illuminated image sensor may be provided in which a structure or arrangement for minimizing a step above the light receiving area which may substantially eliminate or minimize a light interference phenomenon due to metal routing is used.

There are clear competitive advantages to minimizing the size of micro-electronic systems. Chip scale packaging, flip chips, and multichip modules may be applied to various electronic systems, such as mobile phones, hand-held computers, chip cards, and similar devices. Accordingly, there is a need for complex devices having various functions, which often causes an increase in chip areas. Increased chip integration may have a negative impact on manufacturing yield in multi-function devices, which may increase costs due to complexities of device implementation and technical limits. Wiring between sub systems may be limited in terms of performance, multi-functionality, and reliability of micro-electronic systems. These factors may be critical performance bottlenecks in IC generation. Accordingly, 3D integration technology may replace embedded SOC technology in many applications.

In 3D integration technology, a super contact may serve as a pad during packaging and a normal contact for wiring connections and may be formed together on a single wafer. A process of manufacturing a backside-illuminated image sensor according to the related art is described below. First, a super contact hole may be formed to pass through an inter-layer dielectric layer formed on a semiconductor substrate. The semiconductor substrate may include a buried insulating layer that may serve as an etching stop point during back grinding to reach close to the end of the semiconductor substrate. A barrier layer may be formed at the bottom and sidewall of the super contact hole for shielding. An inter-layer dielectric layer may be formed of a silicon oxide film (SiO₂) and a barrier layer may be formed by laminating a silicon nitride film (SiN) and a silicon oxide film. The silicon nitride film may be used because adhesion between the silicon oxide film and silicon is relatively good.

A conductive material may be filled in the super contact hole in which the barrier layer is formed and planarization may be performed to form a super contact. The super contact hole may be filled with tungsten (W). The backside of the semiconductor substrate may be grounded and etched until the buried insulating layer is exposed, thereby performing backside thinning on the backside of the semiconductor substrate.

In the process for manufacturing a backside-illuminated image sensor according to the related art, when a SOI (Silicon On Insulator) wafer is used as a semiconductor substrate, the selection ratio of an oxide film and a silicon nitride film may preferably be equal to or greater than 100:1. In order to form a silicon nitride film satisfying this condition, for example, it may be productive to increase the supply amount of silane (SiH₄) gas in a reaction gas compared to nitrogen (N₂) gas during chemical vapor deposition (CVD).

However, like the process for manufacturing a backside-illuminated image sensor according to the related art, if the supply amount of silane gas in the reaction gas is increased compared to nitrogen gas when forming the silicon nitride film, adhesion between the silicon nitride film and tungsten may not be satisfactory. For example, filling failures may occur or the edge region of the super contact may be lost during planarization after filling when the conductive material filled into the super contact hole, which may cause degradation in yield.

### SUMMARY

In view of the above, embodiments relate to a method of manufacturing a backside-illuminated image sensor in which a metal oxide film containing transition metal is used when forming a barrier layer at the bottom and sidewall of a super contact hole, which may prevent filling failure and loss of an edge region during super contact formation.

Embodiments relate to a method of manufacturing a backside-illumination image sensor. A method may include at least one of: (1) forming an isolation film on the front side of a semiconductor substrate with a buried insulating layer formed therein to define an active region; (2) forming a light-receiving element in the active region of the semiconductor substrate; (3) forming an inter-layer dielectric layer on the front side of the semiconductor substrate on which the light-receiving element is formed; (4) forming a super contact hole to pass through the inter-layer dielectric layer and the buried insulating layer in a pad region defined on the front side of the semiconductor substrate and to reach the semiconductor substrate; (5) forming a barrier layer of a metal oxide film containing transition metal at the bottom and sidewall of the super contact hole; and (6) filling a conductive material in the super contact hole, in which the barrier layer is formed, to form a super contact.

In embodiments, the forming of a barrier layer may be performed such that the barrier layer is formed of at least one of a hafnium oxide film (HfO₂), a titanium oxide film (TiO₂) and a zirconium oxide film (ZrO₂), and/or formed of a stacked film thereof. In embodiments, said forming a barrier layer may be performed such that the barrier layer is formed to have a thickness of 50 Å to 200 Å.

In embodiments, a method may include grinding the backside of the semiconductor substrate at a prescribed thickness and etching the semiconductor substrate using a hydrogen fluoride (HF)-based chemical with the buried insulating layer as an etching stop point. In embodiments, the etching the semiconductor substrate may be performed using a chemical in which a hydrogen fluoride and an ammonium fluoride are mixed. In embodiments, the etching the semiconductor substrate may be performed using spin etching.

In accordance with embodiments, the metal oxide film containing a transition metal may be used when forming the barrier layer at the bottom and sidewall of the super contact hole and/or a high selection ratio may be provided for backside thinning, which may prevent filling failure and loss of the edge region during super contact formation.

### DRAWINGS

The objects and features of embodiments will become apparent from the following description of embodiments given in conjunction with the accompanying drawings, in which:

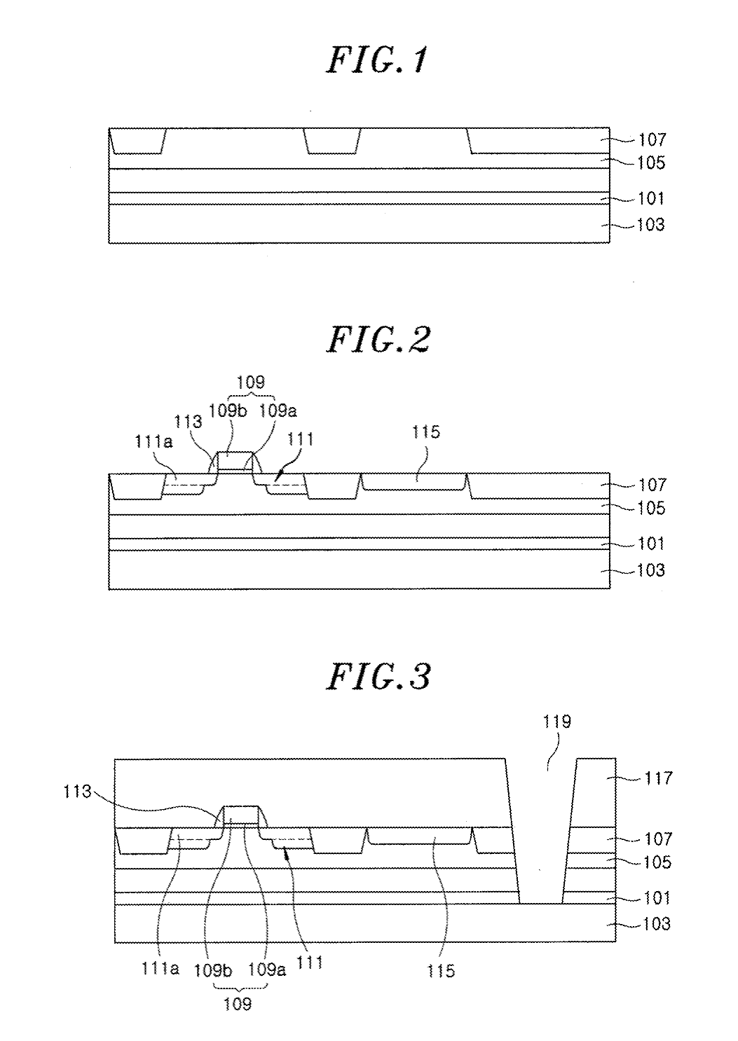

Example FIGS. 1 to 8 are sectional views illustrating a method of manufacturing a backside-illuminated image sensor, according to embodiments.

### DESCRIPTION

Advantages and features of embodiments and methods of accomplishing the same may be understood more readily by reference to the following detailed description of embodiments and the accompanying drawings. Embodiments may, however, be embodied in many different forms and should not be construed as being limited to the embodiments set forth herein. Rather, these embodiments are provided so that this disclosure will be thorough and complete and will fully convey the concept of the embodiments to those skilled in the art, and the embodiments will only be defined by the appended claims.

Example FIGS. 1 to 8 are sectional views illustrating a method of manufacturing a backside-illuminated image sensor, according to embodiments. Example FIG. 1 illustrates a first conduction-type epitaxial layer 105 formed on the front side of a semiconductor substrate 103. A buried insulating layer 101 may be formed of a silicon oxide film (SiO₂), which may use a silicon growth method including epitaxial growth and annealing. An isolation film 107 may be formed locally in the semiconductor substrate 103, on which the epitaxial layer 105 is formed, to define an active region and an inactive region.

Example FIG. 2 illustrates a gate insulating film 109a and a gate conductive film 109b that may be formed on the semiconductor substrate 103 and etched to form a gate electrode 109, and LDD (Lightly Doped Drain) regions 111a of a second conduction type formed in the semiconductor substrate 103 exposed on both sides of the gate electrode 109, in accordance with embodiments. A spacer 113 may be formed on both sides of the gate electrode 109. A lightly doped photodiode 115 of a second conduction type may be formed at a position isolated from the LDD regions 111a by the isolation film 107 in the active region of the semiconductor substrate 103.

Heavily doped source and drain regions 111 of a second conduction type may be formed in the semiconductor substrate 103 exposed on both sides of the spacer 113. In embodiments, the source and drain regions 111 may be formed to be more heavily doped than the LDD regions 111a and the photodiode.

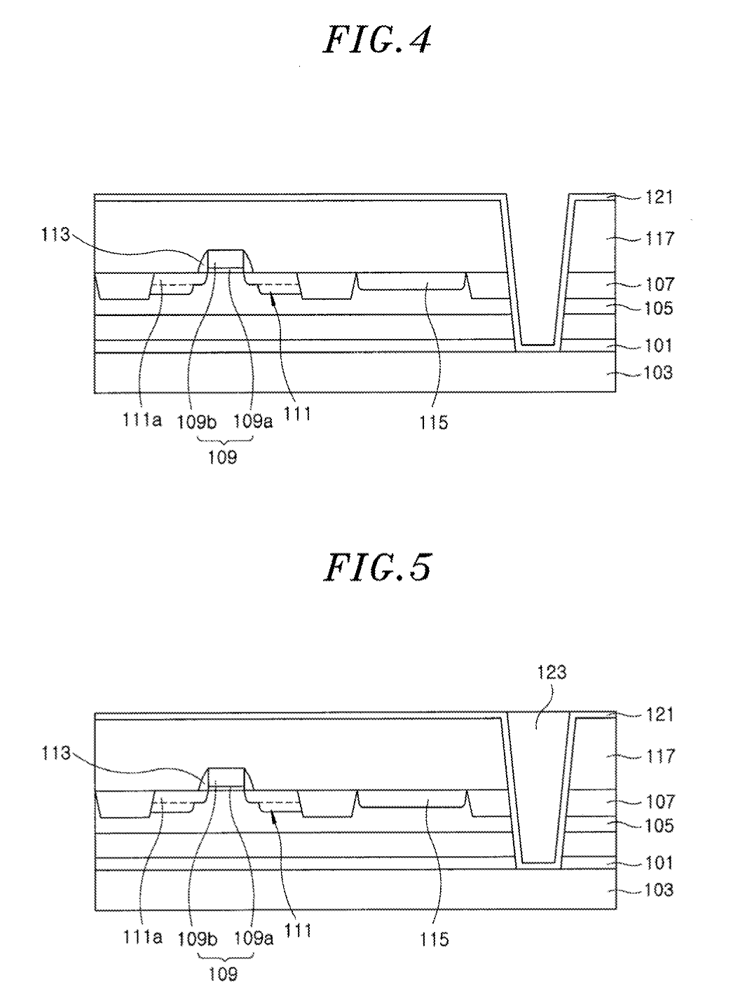

Example FIG. 3 illustrates an inter-layer dielectric layer 117 formed to cover the semiconductor substrate 103 including the gate electrode 109, the spacer 113, the photodiode 115, and the source and drain regions 111. In embodiments, the inter-layer dielectric layer 117 may be formed of an oxide film (e.g. a silicon oxide film). In embodiments, the inter-layer dielectric layer 117 may be formed of at least one of BPSG (BoroPhosphoSilicate Glass), PSG (PhosphoSilicate Glass), BSG (BoroSilicate Glass), USG (Un-doped Silicate Glass), TEOS (Tetra Ethyle Ortho Silicate), and/or a stacked film thereof. In embodiments, the inter-layer dielectric layer 117 may be formed of a film, such as a SOD (Spin On Dielectric) film, which may be coated by spin coating.

Etching may be locally performed on the pad region defined on the front side of the semiconductor substrate 103, on which the inter-layer dielectric layer 117 is formed, to form a super contact hole 119 which passes through the inter-layer dielectric layer 117, the epitaxial layer 105, and the buried insulating layer 101 and reaches the semiconductor substrate 103, in accordance with embodiments. When the isolation film 107 is formed in the pad region, the super contact hole 119 may be formed to pass through the isolation film 107. In embodiments, while dry etching or wet etching may be performed, dry etching may be preferable to form a vertical profile.

Example FIG. 4 illustrates a barrier layer 121 formed of a metal oxide film containing transition metal at the bottom and sidewall of the super contact hole 119 and on the semiconductor substrate 103, in accordance with embodiments. In embodiments, the barrier layer 121 may be formed of one of a hafnium oxide film (HfO₂), a titanium oxide film (TiO₂), a zirconium oxide film (ZrO₂), and/or a stacked film thereof. The barrier layer 121 may be formed by chemical vapor deposition or by atomic layer deposition, in accordance with embodiments. In embodiments, the barrier layer 121 may be formed to have a thickness of 50 Å to 200 Å (e.g. 100 Å).

Example FIG. 5 illustrates the super contact hole 119 in which the barrier layer 121 is formed is filled with a conductive material to form a super contact 123, in accordance with embodiments. In embodiments, examples of the conductive material may include a polysilicon film doped with impurity ions, copper (Cu), platinum (Pt), tungsten (W), aluminum (Al), and an alloy film containing these materials. For example, when tungsten is used as the conductive material, chemical vapor deposition or atomic layer deposition may be performed. For example, when aluminum is used as the conductive material, chemical vapor deposition may be performed. When copper is used as the conductive material, electroplating or chemical vapor deposition may be performed.

Example FIG. 6 illustrates a photoresist pattern 125 formed on the semiconductor substrate 103 in which the super contact 123 is formed, in accordance with embodiments. In embodiments, the barrier layer 121 and the epitaxial layer 105 locally exposed may be etched to form a normal contact hole 127 to expose the gate electrode 109 or the source and drain regions 111.

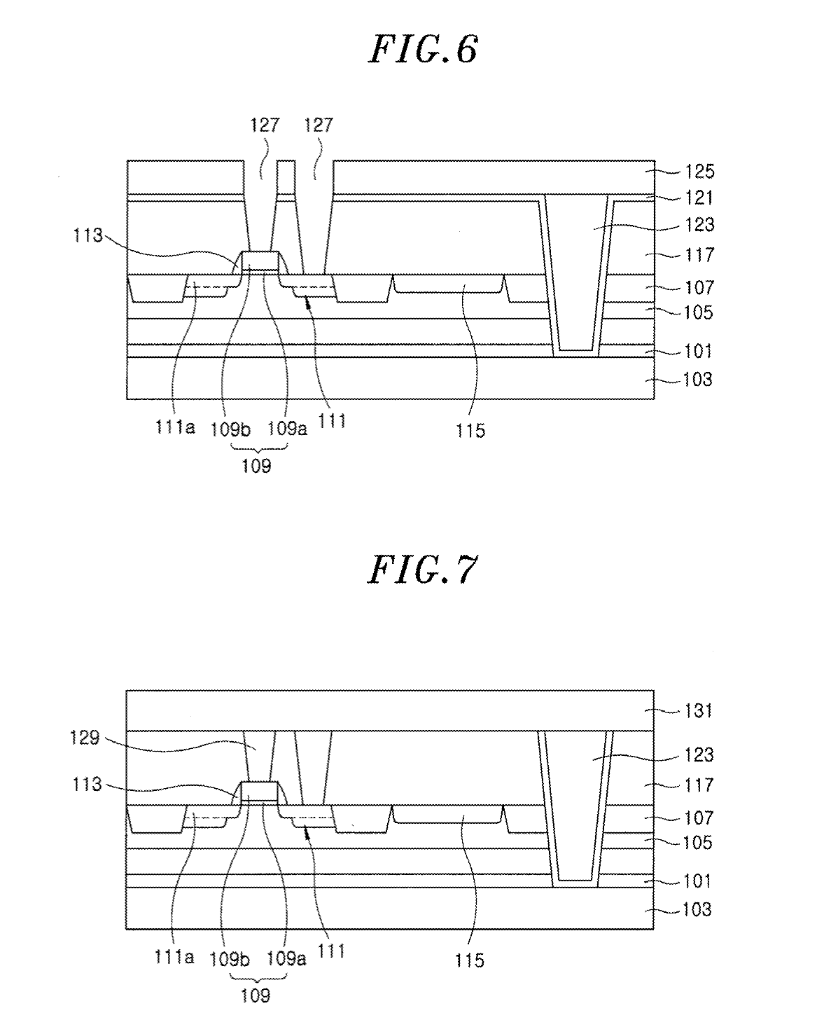

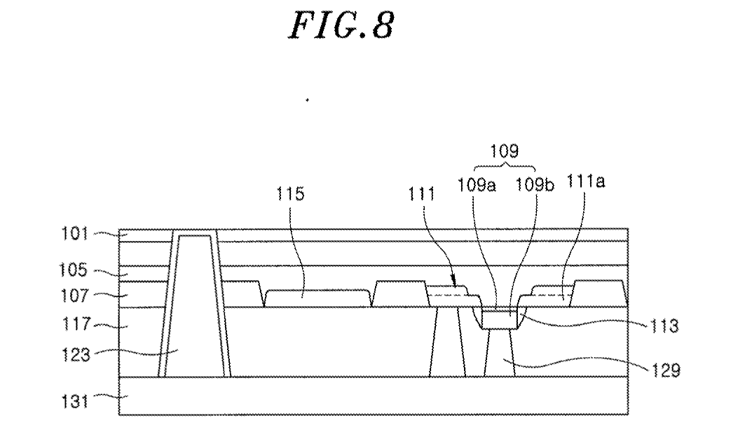

Example FIG. 7 illustrates the photoresist pattern 125 removed and the normal contact hole 127 is then filled with a conductive material to form a normal contact 129, in accordance with embodiments. In embodiments, examples of the conductive materials include at least one of a polysilicon film doped with impurity ions, copper (Cu), platinum (Pt), tungsten (W), aluminum (Al), and/or an alloy film containing these materials. A support substrate 131 may be stacked on the front side of the semiconductor substrate 103 in which the normal contact 129 is formed, in accordance with embodiments. In embodiments, the support substrate 131 and the semiconductor substrate 103 may be bonded. In embodiments, as the bonding method, one of oxide film-oxide film bonding, oxide film-silicon bonding, oxide film-metal film bonding, oxide film-adhesive member-oxide film bonding, and/or oxide film-adhesive member-silicon bonding may be used.

Example FIG. 8 illustrates the backside of the semiconductor substrate 101 bonded to the support substrate 131 is ground at a prescribed thickness, in accordance with embodiments. In embodiments, backside thinning may be performed to etch the ground semiconductor substrate 103 using a hydrogen fluoride (HF)-based chemical with the buried insulating layer 101 as an etching stop point. In embodiments, spin etching may be performed using a chemical in which a hydrogen fluoride and an ammonium fluoride are mixed.

Since the barrier layer 121 may be formed of a metal oxide film containing transition metal, a high selection ratio may be provided between the barrier layer 121 and the buried insulating layer 101. For example, the selection ratio between the hafnium oxide film and the silicon oxide film is equal to or greater than 100:1, even when the barrier layer 121 is deposited at a thickness equal to or greater than 100 Å, such that sufficient effects may be obtained, in accordance with embodiments.

A conductive material for another pad may be formed on the exposed semiconductor substrate 103, in accordance with embodiments. In embodiments, examples of the conductive material include metal and a mixed film in which at least two kinds of metal are mixed.

Steps of forming a color filter and a step of forming a micro-lens may be selectively performed, in accordance with embodiments. A protective film may be formed on the semiconductor substrate 103 and a color filter may be formed on the protective film corresponding to the photodiode 115, in accordance with embodiments. A lower planarization film may be formed on the protective film before forming the color filter, in accordance with embodiments. In embodiments, an upper planarization film may be formed to cover the color filter and a micro-lens may be formed on the upper planarization film to correspond to the color filter. A low-temperature oxide film may be formed on the protective film including the micro-lens. In embodiments, packing may be performed to package the semiconductor substrate 103 and the support substrate 131. In embodiments, packing includes wire bonding and sawing. Wire bonding may be performed by connecting a pad and an external chip through wires.

While embodiments have been shown and described, it will be understood by those skilled in the art that various changes and modifications may be made without departing from the scope of the embodiments as defined in the following claims.

What is claimed is:

1. A method comprising:
forming an isolation film at least one of on or over the front side of a semiconductor substrate, wherein the semiconductor substrate comprises a buried insulating layer formed therein to define at least one active region;
forming a light-receiving element in the active region of the semiconductor substrate;
forming an inter-layer dielectric layer at least one of on or over the front side of the semiconductor substrate on which the light-receiving element is formed;
forming a super contact hole that passes through the inter-layer dielectric layer and the buried insulating layer in a pad region defined on the front side of the semiconductor substrate, wherein the super contact hole reaches the semiconductor substrate;
forming a barrier layer of a metal oxide film containing transition metal at the bottom and sidewall of the super contact hole; and
filling a conductive material into the super contact hole, in which the barrier layer is formed, to form a super contact.

2. The method of claim 1, wherein the method is for manufacturing a backside-illumination image sensor.

3. The method of claim 1, wherein said forming a barrier layer is performed such that the barrier layer is formed of at least one of a hafnium oxide film (HfO₂), a titanium oxide film (TiO₂)and a zirconium oxide film (ZrO₂), or stacked film thereof.

4. The method of claim 3, wherein said forming a barrier layer is performed such that the barrier layer is formed to have a thickness of between approximately 50 Å to 200 Å.

5. The method of claim 1, comprising:
grinding the backside of the semiconductor substrate at a prescribed thickness; and
etching the semiconductor substrate using a hydrogen fluoride (HF)-based chemical with the buried insulating layer as an etching stop point.

6. The method of claim 5, wherein said etching the semiconductor substrate is performed using a chemical in which a hydrogen fluoride and an ammonium fluoride are mixed.

7. The method of claim 6, wherein said etching the semiconductor substrate is performed using spin etching.

8. An apparatus comprising:
an isolation film at least one of on or over the front side of a semiconductor substrate, wherein the semiconductor substrate comprises a buried insulating layer formed therein to define at least one active region;
a light-receiving element in the active region of the semiconductor substrate;
an inter-layer dielectric layer at least one of on or over the front side of the semiconductor substrate on which the light-receiving element is formed;
a super contact hole that passes through the inter-layer dielectric layer and the buried insulating layer in a pad region defined on the front side of the semiconductor substrate, wherein the super contact hole reaches the semiconductor substrate;
a barrier layer of a metal oxide film containing transition metal at the bottom and sidewall of the super contact hole; and
a super contact comprising a conductive material filled into the super contact hole in which the barrier layer is formed.

9. The apparatus of claim 8, wherein the apparatus is a backside-illumination image sensor.

10. The apparatus of claim 8, wherein the barrier layer comprises at least one of a hafnium oxide film (HfO₂), a titanium oxide film (TiO₂)and a zirconium oxide film (ZrO₂), or stacked film thereof.

11. The apparatus of claim 10, wherein said barrier layer has a thickness of between approximately 50 Å to 200 Å.

12. The apparatus of claim 8, wherein:
the backside of the semiconductor substrate is grinded to a prescribed thickness; and
the semiconductor substrate is etched using a hydrogen fluoride (HF)-based chemical with the buried insulating layer as an etching stop point.

13. The apparatus of claim 12, wherein the semiconductor substrate is etched using a chemical in which a hydrogen fluoride and an ammonium fluoride are mixed.

14. The apparatus of claim 13, wherein the semiconductor substrate is etched using spin etching.
